(19) United States
(12) Patent Application Publication
(10) Pub. No.: US 2023/0335410 A1
(43) Pub. Date: Oct. 19, 2023

(54) SEMICONDUCTOR DEVICE MANUFACTURING METHOD, AND SEMICONDUCTOR DEVICE

(71) Applicant: Mitsubishi Electric Corporation, Tokyo (JP)

(72) Inventors: Akira KIYOI, Tokyo (JP); Naoyuki KAWABATA, Tokyo (JP); Tsuyoshi KAWAKAMI, Tokyo (JP)

(73) Assignee: Mitsubishi Electric Corporation, Tokyo (JP)

(21) Appl. No.: 18/028,808

(22) PCT Filed: Dec. 15, 2020
(86) PCT No.: PCT/JP2020/046653

§ 371 Date: Mar. 28, 2023

(51) Int. Cl. H01L 21/322; H01L 21/304; H01L 29/861; H01L 29/66; H01L 29/739

(52) U.S. Cl. CPC H01L 21/3225; H01L 21/304; H01L 29/861; H01L 29/66348; H01L 29/6609; H01L 29/7397

(57) ABSTRACT

It is an object to provide technology enabling reduction in variation of an oxygen concentration among silicon wafers. A semiconductor device manufacturing method includes: a first step of introducing oxygen to increase an oxygen concentration of a silicon wafer when the oxygen concentration of the silicon wafer is lower than a predetermined threshold, and deriving oxygen to decrease the oxygen concentration of the silicon wafer when the oxygen concentration of the silicon wafer is higher than the threshold; a second step of forming a first surface structure; a third step of grinding the silicon wafer from a second surface; and a fourth step of forming a second surface structure.

### TECHNICAL FIELD

The present disclosure relates to semiconductor device manufacturing methods and semiconductor devices.

### BACKGROUND ART

In a power semiconductor device as a type of a semiconductor device, point defects and impurities present in a silicon wafer are sometimes combined to form composite defects for faster switching. Patent Document 1 and Patent Document 2 disclose that formation of the composite defects in the power semiconductor device allows for reduction in switching losses, improvement in reverse recovery characteristics (e.g., reduction in recovery surge voltage), improvement in short circuit withstand, and the like in addition to improvement in switching characteristics.

### PRIOR ART DOCUMENTS

### Patent Documents

Patent Document 1: WO 2007/000838
Patent Document 2: WO 2016/204097

### SUMMARY

### Problem to be Solved by the Invention

However, there has been a problem in that characteristics of the power semiconductor device might vary as a concentration of oxygen which is one of the impurities forming the composite defects varies among silicon wafers due to a manufacturing variation among the silicon wafers.

The present disclosure has been conceived in view of a problem as described above, and it is an object of the present disclosure to provide technology enabling reduction in variation of an oxygen concentration among silicon wafers.

### Means to Solve the Problem

A semiconductor device manufacturing method according to the present disclosure includes: a first step of introducing oxygen to increase an oxygen concentration of a silicon wafer when the oxygen concentration of the silicon wafer is lower than a predetermined threshold, and deriving oxygen to decrease the oxygen concentration of the silicon wafer when the oxygen concentration of the silicon wafer is higher than the threshold; a second step of forming a first surface structure in a first surface of the silicon wafer after the first step; a third step of grinding the silicon wafer from a second surface opposite the first surface after the first step; and a fourth step of forming a second surface structure in the second surface of the silicon wafer after the third step.

### Effects of the Invention

According to the present disclosure, oxygen is introduced to increase the oxygen concentration of the silicon wafer when the oxygen concentration of the silicon wafer is lower than the threshold, and oxygen is derived to decrease the oxygen concentration of the silicon wafer when the oxygen concentration of the silicon wafer is higher than the threshold. According to such a configuration, a variation of an oxygen concentration among silicon wafers can be reduced.

The objects, features, aspects and advantages of the present disclosure will become more apparent from the following detailed description and the accompanying drawings.

### BRIEF DESCRIPTION OF DRAWINGS

FIG. 1 is a flowchart showing a power semiconductor device manufacturing method according to Embodiment 1.

FIG. 2 is a diagram for describing an oxygen introducing and deriving step according to Embodiment 1.

FIG. 3 is a diagram for describing the oxygen introducing and deriving step according to Embodiment 1.

FIG. 4 is a diagram for describing the oxygen introducing and deriving step according to Embodiment 1.

FIG. 5 is a diagram for describing a grinding step according to Embodiment 1.

FIG. 6 is a diagram showing a result of the power semiconductor device manufacturing method according to Embodiment 1.

FIG. 7 is a partial cross-sectional view illustrating a main part of a configuration of a power semiconductor device according to Embodiment 2.

FIG. 8 is a partial cross-sectional view illustrating a main part of a configuration of a power semiconductor device according to Embodiment 2.

FIG. 9 is a partial cross-sectional view illustrating a main part of a configuration of a power semiconductor device according to Embodiment 3.

FIG. 10 is a partial cross-sectional view illustrating a main part of a configuration of a power semiconductor device according to Embodiment 3.

### DESCRIPTION OF EMBODIMENTS

### Embodiment 1

Before description of a method for manufacturing a power semiconductor device as a semiconductor device according to Embodiment 1, composite defects will be described.

The composite defects are formed by combining point defects and impurities present in a silicon wafer used for the power semiconductor device. The impurities include oxygen, carbon, and nitrogen originally contained in the silicon wafer, and Embodiment 1 focuses on oxygen as such impurities. The point defects are local disorders of a crystal lattice, and include those of a vacancy type and those of an interstitial silicon type.

The composite defects formed by combining the point defects and the impurities form a deep energy level, so that holes and electrons are recombined at the composite defects. Control of the composite defects formed in the silicon wafer thus allows for control of a carrier lifetime of the power semiconductor device. As a result, an on-resistance of the power semiconductor device slightly increases, but a faster switching speed is enabled. Formation of the composite defects in the power semiconductor device also allows for reduction in switching losses, improvement in reverse recovery characteristics (e.g., reduction in recovery surge voltage), improvement in short circuit withstand, and the like in addition to improvement in switching characteristics.

The composite defects are often formed in the silicon wafer using charged particle irradiation. At least one of electrons or light-element ions (protons and helium ions) are used as a charged particle beam. Point defects are formed in a region of the silicon wafer irradiated with the charged particle beam.

A quantity of oxygen originally contained in the silicon wafer and used to form the composite defects typically varies among silicon wafers. This is attributed to a process for manufacturing an ingot used to form the silicon wafers. There are two methods for manufacturing a silicon ingot for power semiconductor devices: the magnetic Czochralski (MCZ) method and the floating-zone (FZ) method. In the MCZ method, a quartz crucible is used to manufacture the ingot, and thus oxygen eluted from the quartz crucible is taken into the ingot. As a result, an oxygen concentration of the ingot manufactured by the MCZ method typically tends to be approximately hundreds to thousands of times higher than an oxygen concentration of the ingot manufactured by the FZ method. In the ingot manufactured by the MCZ method, an oxygen concentration varies between an upper portion and a lower portion of the ingot due to the segregation phenomenon between the ingot and a silicon melt. An oxygen concentration of the silicon wafer thus varies depending on a location where the silicon wafer is cut out of the ingot.

It is estimated that a quantity of composite defects is strongly affected by a smaller one of a quantity of oxygen and a quantity of point defects involved in combination. Since the oxygen concentration of the silicon wafer varies among silicon wafers, characteristics (e.g., the switching speed and an on-voltage) of power semiconductor devices formed out of a plurality of silicon wafers might vary. As a result, characteristics of the power semiconductor device might not meet the standards for the power semiconductor device, leading to reduction in yield.

In contrast, according to a power semiconductor device manufacturing method according to Embodiment 1 described below, a variation of the oxygen concentration among silicon wafers and, further, a variation of characteristics among power semiconductor devices can be reduced.

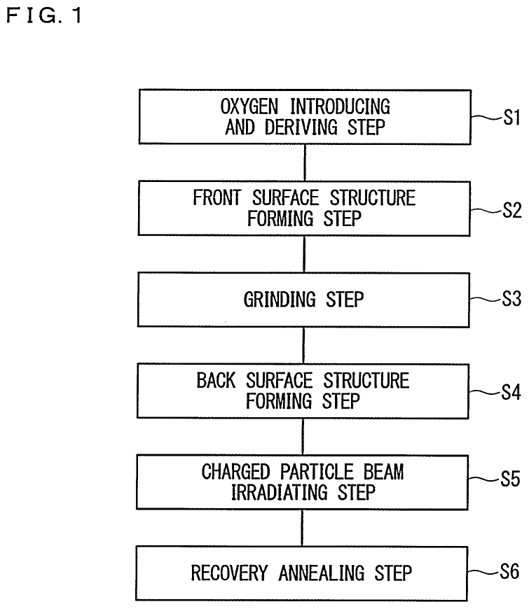

FIG. 1 is a flowchart showing the power semiconductor device manufacturing method according to Embodiment 1. As one example of the manufacturing method, a manufacturing method for manufacturing a vertical diode having a thickness of 60 μm out of an n-type or n⁻-type silicon wafer is herein described.

Before the start of step S1, a silicon wafer cut out of an ingot and having a front surface (first surface) and a back surface (second surface) opposite the front surface is prepared. The silicon wafer before step S1 has an oxygen concentration of 1×10¹⁵ cm⁻³ or more and 1×10¹⁸ cm⁻³ or less, for example. The oxygen concentration can be measured by infrared absorption measurement and secondary-ion mass spectrometry, for example. The silicon wafer is thinner than the ingot, and thus can be considered to have a uniform oxygen concentration in a depth direction.

<Oxygen Introducing and Deriving Step (First Step)>

In step S1 in FIG. 1, an oxygen introducing and deriving step of actively controlling an oxygen concentration of the silicon wafer is performed. In Embodiment 1, the silicon wafer is annealed in a state of being in contact with at least one of an oxide film or an oxygen atmosphere in the oxygen introducing and deriving step. For example, the silicon wafer is annealed in a furnace, such as a vertical furnace, in a temperature range of 1000° C. to 1300° C. (627 K to 1027 K) in a state of the front surface of the silicon wafer being capped with the oxide film or the front surface of the silicon wafer being exposed to the oxygen atmosphere.

In annealing, a phenomenon in which oxygen in the oxide film or the oxygen atmosphere is introduced into the silicon wafer or a phenomenon in which oxygen in the silicon wafer is derived to the oxide film or the oxygen atmosphere occurs. An equilibrium concentration of oxygen between the silicon wafer and an outside (hereinafter simply referred to as the “equilibrium concentration”) affects whether introduction or derivation is performed. That is to say, introduction to transfer oxygen from the outside, such as the oxide film, to the silicon wafer is performed when a concentration of oxygen originally contained in the silicon wafer is lower than the equilibrium concentration. On the other hand, derivation to transfer oxygen from the silicon wafer to the outside, such as the oxide film and the atmosphere, is performed when the concentration of oxygen originally contained in the silicon wafer is higher than the equilibrium concentration. Use of the oxide film cap can suppress excessive introduction and derivation of oxygen.

A result of practice of the oxygen introducing and deriving step will be described below. A wafer A and a wafer B were used as the worst case of the variation of the oxygen concentration among silicon wafers for power semiconductor devices. A silicon wafer having an oxygen concentration of 1×10¹⁵ cm⁻³ was used as the wafer A, and a silicon wafer having an oxygen concentration of 1×10¹⁸ cm⁻³ was used as the wafer B.

Annealing was performed at 1150° C. in a state of front surfaces of the wafer A and the wafer B being thermally oxidized, and changes in oxygen concentrations of the wafer A and the wafer B were examined while an annealing time was set at ten levels (2.6 h, 5 h, 10 h, 15 h, 20 h, 25 h, 36 h, 50 h, 70 h, and 100 h).

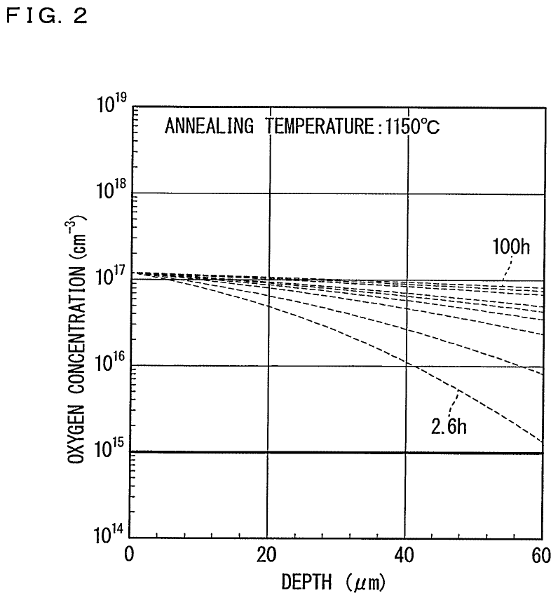

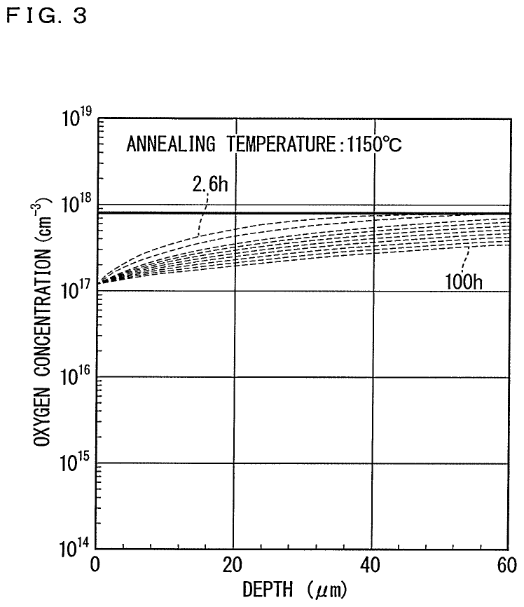

FIGS. 2 and 3 are diagrams showing results thereof. Specifically, FIG. 2 is a diagram showing a relationship between a depth from the front surface and the oxygen concentration of the wafer A, and FIG. 3 is a diagram showing a relationship between a depth from the front surface and the oxygen concentration of the wafer B. The equilibrium concentration (a predetermined threshold) in cases of FIGS. 2 and 3 is approximately 1×10¹⁷ cm⁻³.

When the oxygen concentration of the silicon wafer shown in a solid line in FIG. 2 was lower than the equilibrium concentration as shown in FIG. 2, oxygen was introduced to increase the oxygen concentration of the silicon wafer, and oxygen concentration distribution transitioned from that shown in a thick line in FIG. 2 to that shown in dotted lines in FIG. 2. On the other hand, when the oxygen concentration of the silicon wafer shown in a solid line in FIG. 3 was higher than the equilibrium concentration as shown in FIG. 3, oxygen was derived to decrease the oxygen concentration of the silicon wafer, and the oxygen concentration distribution transitioned from that shown in a thick line in FIG. 3 to that shown in dotted lines in FIG. 3.

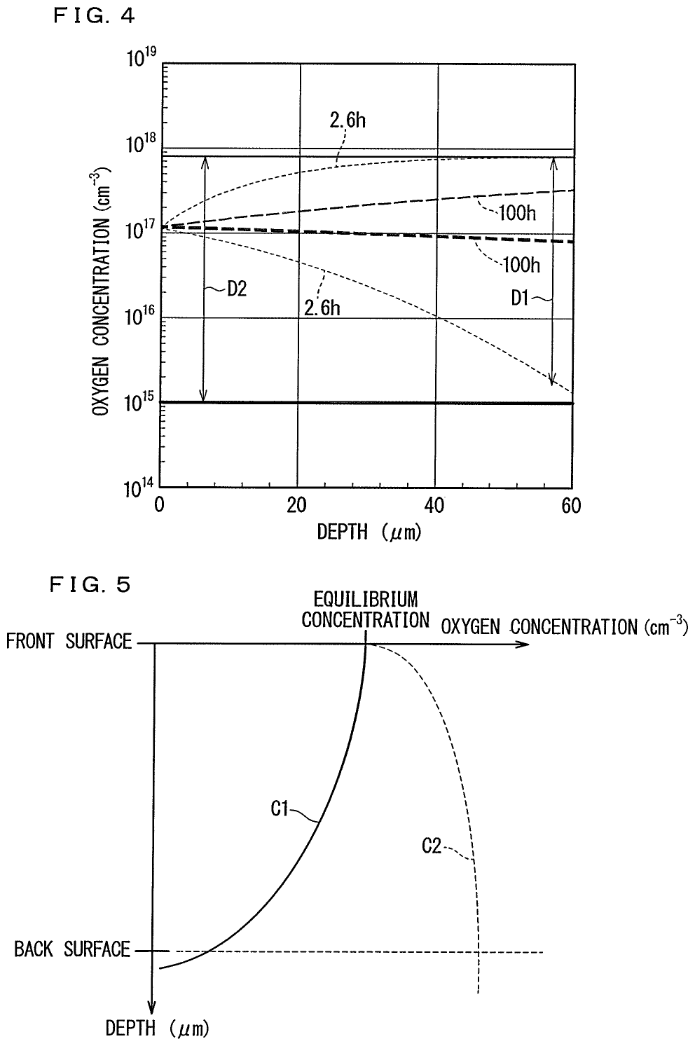

FIG. 4 shows oxygen concentrations of the wafer A and oxygen concentrations of the wafer B before the oxygen introducing and deriving step, after the oxygen introducing and deriving step for approximately 2.6 h to 2.7 h, and after the oxygen introducing and deriving step for 100 h. An oxygen concentration difference D1 between the wafer A and the wafer B after the oxygen introducing and deriving step was smaller than an oxygen concentration difference D2 before the oxygen introducing and deriving step. As the annealing time increased, the oxygen concentration transitioned from that shown in thin dotted lines in FIG. 4 to that shown in thick dotted lines, the oxygen concentration difference between the wafer A and the wafer B decreased, and a depth to which the oxygen concentration difference was reduced increased.

An annealing condition in the oxygen introducing and deriving step will be described next. Herein, t (seconds) is the annealing time, T (K) is an annealing temperature of 1000° C. or more and 1300° C. or less, d (cm) is a thickness of a portion of the silicon wafer corresponding to the silicon wafer after a grinding step, which will be described below, and k is the Boltzmann constant in eV/K. In this case, equations (1) to (3) below preferably hold. In the equation (1) below, erfc⁻¹ is an inverse function of a complementary error function erfc.

t≥{d/[2×√D×erfc⁻¹(1×10¹⁵/Cₛ)]}² (1)

D=0.28×exp(−2.53/kT) (2)

Cₛ=6×10²²exp(−1.61/kT) (3)

When the thickness d is 60 and the annealing temperature T is 1150° C., for example, the equation (1) above becomes t≥8203, which indicates that annealing time t is preferably 2.3 h or more. When the annealing time t is shorter than a lower limit in the equation (1) above, introduction or derivation of oxygen is not sufficient, oxygen originally contained in the silicon wafer widely remains, and thus a variation of the oxygen concentration among silicon wafers is relatively large. In contrast, when the annealing time t is longer than the lower limit in the equation (1) above, the variation of the oxygen concentration among silicon wafers is relatively small. As can be seen from FIGS. 2 to 4, the variation of the oxygen concentration can further be reduced when an equation (4) below holds in which the lower limit of the annealing time t is longer than that in the equation (1) above. The variation of the oxygen concentration can further be reduced when an equation (5) below holds in which the lower limit of the annealing time t is longer than that in the equation (4) below.

t≥{d/[2×√D×erfc⁻¹(1×10¹⁶/Cₛ)]}² (4)

t≥{d/[2×√D×erfc⁻¹(1×10¹⁷/Cₛ)]}² (5)

When the annealing temperature T is low, the annealing time t to be the lower limit in the equation (1) above is long, and manufacturing efficiency is low. On the other hand, an annealing temperature T of more than 1300° C. is not preferable as the silicon wafer might melt. In light of these circumstances, the annealing temperature T is preferably set in a range of 1000° C. to 1300° C.

The oxygen concentration of the front surface of the silicon wafer after the oxygen introducing and deriving step is the equilibrium concentration determined by the annealing temperature T. The equilibrium concentration is 2×10¹⁶ cm⁻³ or more and 5×10¹⁷ cm⁻³ or less in the temperature range of 1000° C. to 1300° C. In a region shallower than a diffusion length of oxygen, the oxygen concentration of the silicon wafer is adjusted within the range of the equilibrium concentration.

As described above, the oxygen concentration difference (D1 in FIG. 4) between the wafer A and the wafer B after the oxygen introducing and deriving step is smaller than an oxygen concentration difference (D2 in FIG. 4) of approximately 1×10¹⁸ cm⁻³ before the oxygen introducing and deriving step.

<Front Surface Structure Forming Step (Second Step)>

In step S2 in FIG. 1, a front surface structure forming step of forming a front surface structure (first surface structure) of a diode in the front surface of the silicon wafer is performed. In the front surface structure forming step according to Embodiment 1, ion implantation of p-type impurities, such as boron, and activation annealing to activate the p-type impurities to form a p⁺-type anode region in the front surface of the silicon wafer are performed. An anode electrode is then formed on the anode region.

<Grinding Step (Third Step)>

In step S3 in FIG. 1, a grinding step of grinding the silicon wafer from the back surface so that the silicon wafer has a desired thickness is performed. In the grinding step, after protection of the front surface structure, the back surface of the silicon wafer is ground using a grinding means, such as a chemical mechanical polish (CMP), for example. In description made below, the silicon wafer after grinding is also referred to as a semiconductor region.

FIG. 5 is a diagram schematically showing an oxygen concentration of the semiconductor region of the power semiconductor device according to Embodiment 1, that is, an oxygen concentration of the silicon wafer after the grinding step. Due to the oxygen introducing and deriving step in step S1, the variation of the oxygen concentration among silicon wafers is sufficiently suppressed on a side of the front surface of the silicon wafer. On a side of the back surface of the silicon wafer, however, the variation of the oxygen concentration among silicon wafers is sometimes not sufficiently suppressed depending on the annealing time.

The grinding step of grinding the silicon wafer from the back surface is thus performed in step S3, so that the variation of the oxygen concentration among silicon wafers is sufficiently suppressed also on the side of the back surface of the silicon wafer. In Embodiment 1, an entire portion or a portion on the side of the front surface of the silicon wafer after the grinding step has an oxygen concentration of 2×10¹⁶ cm⁻³ or more and 5×10¹⁷ cm⁻³ or less.

Even after grinding, however, distribution in which the oxygen concentration is slightly non-uniform is present in the depth direction of the silicon wafer. A non-uniform state herein refers to a state in which the oxygen concentration is lower on a bulk side than in the front surface of the silicon wafer (a state C1 in FIG. 5) or a state in which the oxygen concentration is higher on the bulk side than in the front surface of the silicon wafer (a state C2 in FIG. 5) and a state in which the oxygen concentration has a gradient throughout the silicon wafer.

<Back Surface Structure Forming Step (Fourth Step)>

In step S4 in FIG. 1, a back surface structure forming step of forming a back surface structure (second surface structure) of the diode in the front surface of the silicon wafer is performed. In the back surface structure forming step according to Embodiment 1, ion implantation of n-type impurities, such as phosphorus, into the back surface of the n-type or n⁻-type silicon wafer and activation annealing to activate the n-type impurities to form a cathode region in the back surface of the silicon wafer are performed. A cathode electrode is then formed on the cathode region.

<Charged Particle Beam Irradiating Step (Fifth Step)>

In step S5 in FIG. 1, a charged particle beam irradiating step of irradiating the silicon wafer with the charged particle beam to form points defect is performed.

In Embodiment 1, the front surface (an anode side) of the silicon wafer is irradiated with an electron beam as the charged particle beam to uniformly form the point defects in the entire portion of the silicon wafer. The back surface (a cathode side) of the silicon wafer may be irradiated with the electron beam as needed. When the electron beam is used as the charged particle beam, an accelerator may be used to irradiate the silicon wafer with electrons accelerated to several hundred kilo electron volts to several tens of mega electron volts. A dose of the electron beam is 1×10¹² cm⁻² to 1×10¹⁵ cm⁻², for example.

Irradiation with the charged particle beam is not limited to that described above, and the front surface or the back surface of the silicon wafer may be irradiated with protons or helium ions as the charged particle beam to form the point defects in a local portion of the silicon wafer, for example.

<Recovery Annealing Step (Sixth Step)>

In step S6 in FIG. 1, a recovery annealing step is performed as annealing for at least one of formation of composite defects including the point defects and oxygen or annihilation of some of the point defects. In the recovery annealing step, the silicon wafer is annealed in an inert gas atmosphere, such as nitrogen, in a range of 200° C. to 500° C., for example. In the recovery annealing step, oxygen in the semiconductor region, that is, oxygen including oxygen originally contained in the silicon wafer and oxygen introduced and derived in the oxygen introducing and deriving step reacts with the point defects to form the composite defects. Annealing at a temperature of less than 200° C. is not preferable as efficiency of formation of the composite defects is reduced. Annealing at a temperature of more than 500° C. is not preferable as diffusion and annihilation of the point defects become noticeable. The annealing temperature is thus preferably in a range of 200° C. to 500° C.

Due to irradiation with the charged particle beam and recovery annealing of the silicon wafer, the composite defects are efficiently formed. The composite defects formed by the processing are vacancy-oxygen pair (VO) defects and interstitial carbon-interstitial oxygen pair (CiOi) defects, for example.

A process of forming the composite defects is herein described in detail. When the semiconductor region is irradiated with the electron beam, silicon is ejected from a normal lattice location by electron energy, and a vacancy (V) as a type of a point defect and interstitial silicon (I) as a type of a point defect are formed. The vacancy and the interstitial silicon are thermally unstable, and react with oxygen or carbon as impurities present around them to form composite defects, which are thermally stable. For example, the vacancy and oxygen form a VO defect having an energy level of approximately 0.17 eV below the conduction band. The interstitial silicon is replaced with carbon to form interstitial carbon (Ci). The interstitial carbon and oxygen form a CiOi defect having an energy level of approximately 0.36 eV above the valence band.

A result of trial calculation of the effect of the power semiconductor device manufacturing method according to Embodiment 1 will be described next. Herein, the wafer A and the wafer B described above were used to manufacture vertical diodes each having a thickness of 60 μm, and a drift layer voltage Vm corresponding to on-characteristics of each of them was examined. The charged particle beam was the electron beam, and typically formed composite defects were VO defects and CiOi defects.

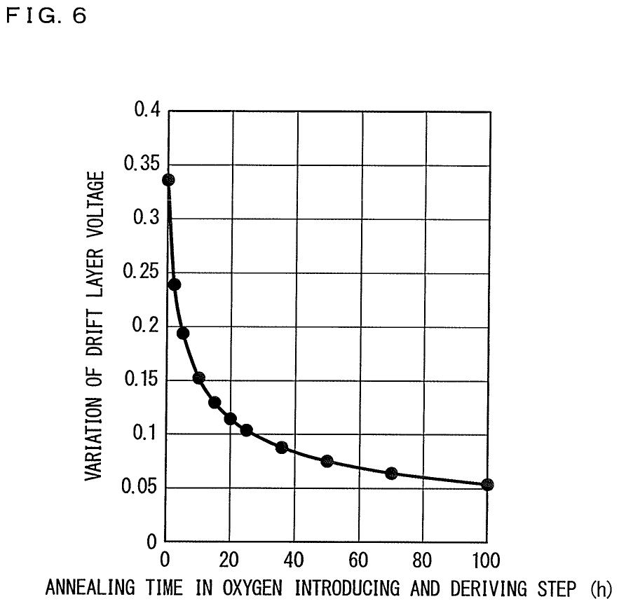

FIG. 6 is a diagram showing the result, and is specifically a diagram showing a relationship between a variation of the drift layer voltage Vm between diodes and the annealing time in the oxygen introducing and deriving step. The variation of the drift layer voltage Vm shows a variation of the drift layer voltage between a diode formed out of the wafer A and a diode formed out of the wafer B. More specifically, the wafer B has more composite defects than the wafer A, and has a higher drift layer voltage than the wafer A, so that the variation of the drift layer voltage Vm corresponds to a value obtained by subtracting the drift layer voltage of the wafer A from the drift layer voltage of the wafer B.

A typical power semiconductor device manufacturing method corresponds to a case where the annealing time in the oxygen introducing and deriving step is zero, and, in the manufacturing method, the variation of the drift layer voltage Vm was 0.34 V.

In contrast, in the power semiconductor device manufacturing method according to Embodiment 1, when the annealing temperature in the oxygen introducing and deriving step was set to 1150° C., and the annealing time was set to 2.6 h to 2.7 h corresponding to the lower limit in the equation (1), the variation of the drift layer voltage Vm was reduced to 0.24 V. When the annealing time in the oxygen introducing and deriving step was increased to 100 h, the variation of the drift layer voltage Vm was reduced to 0.05 V.

The worst case of the variation of the oxygen concentration among silicon wafers for power semiconductor devices was assumed in description made above. Even if the oxygen concentration is lower or higher than that in this case, however, it is obvious that an effect similar to the above-mentioned effect can be obtained according to the power semiconductor device manufacturing method according to Embodiment 1. The effect of the power semiconductor device manufacturing method according to Embodiment 1 is thus not limited to an original oxygen concentration of the silicon wafer.

Characteristics of the power semiconductor device are affected by a structure of the power semiconductor device and a concentration of impurities other than oxygen, and are also strongly affected by an oxygen concentration of a bulk. Thus, according to the manufacturing method according to Embodiment 1, a variation of any oxygen concentration of the bulk can be suppressed by performing the oxygen introducing and deriving step, so that a variation of characteristics of the power semiconductor device can be suppressed.

### Summary of Embodiment 1

In the power semiconductor device manufacturing method according to Embodiment 1 as described above, the oxygen introducing and deriving step of changing the oxygen concentration of the silicon wafer relative to the equilibrium concentration (predetermined threshold) is performed. According to such a manufacturing method, the oxygen concentration of the silicon wafer (semiconductor region) can be adjusted, and the variation of the oxygen concentration among silicon wafers can be suppressed. As a result, a variation of a concentration of a composite defect including oxygen functioning as a trap and, further, a variation of characteristics, such as the on-voltage, among power semiconductor devices formed out of different silicon wafers can be suppressed.

Furthermore, according to Embodiment 1, a power semiconductor device including the semiconductor region of the silicon wafer having a composite defect including oxygen and a point defect, the front surface structure disposed in the front surface of the semiconductor region, and the back surface structure disposed in the back surface of the semiconductor region can be formed. The power semiconductor device can be formed so that an entire portion or a portion on a side of the front surface of the semiconductor region has an oxygen concentration of 1×10¹⁷ cm⁻³ to 8×10¹⁷ cm⁻³, and an oxygen concentration from the front surface to the back surface of the semiconductor region varies continuously as shown in FIG. 5.

### Embodiment 2

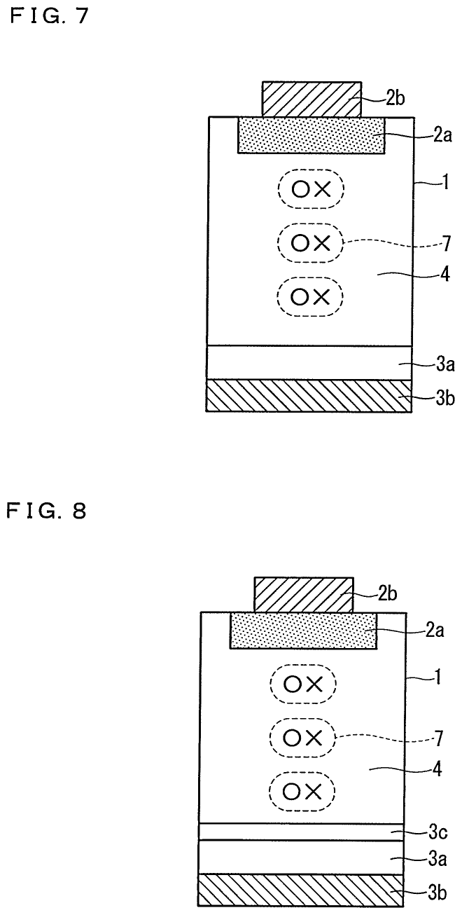

FIG. 7 is a partial cross-sectional view illustrating a main part of a configuration of a power semiconductor device according to Embodiment 2. From among components according to Embodiment 2, components different from the above-mentioned components will mainly be described below. The power semiconductor device according to Embodiment 2 is a vertical diode having composite defects formed in the semiconductor region by the manufacturing method according to Embodiment 1.

The vertical diode in FIG. 7 includes a semiconductor region 1, an anode region 2a, a cathode region 3a, a drift region 4, an anode electrode 2b, and a cathode electrode 3b. The anode region 2a and the anode electrode 2b are included in the concept of the front surface structure in Embodiment 1, and the cathode region 3a and the cathode electrode 3b are included in the concept of the back surface structure in Embodiment 1.

The semiconductor region 1 is included in the semiconductor region in Embodiment 1, and is formed out of the silicon wafer. The semiconductor region 1 includes the anode region 2a including the p-type impurities (typically boron) at a relatively high concentration, the cathode region 3a including the n-type impurities (typically phosphorus) at a relatively high concentration, and the drift region 4 disposed between the anode region 2a and the cathode region 3a. The drift region 4 may include the n-type impurities at a relatively low concentration, or may not substantially include impurities of a conductivity type. The anode electrode 2b is electrically connected to the anode region 2a, and the cathode electrode 3b is electrically connected to the cathode region 3a.

In the semiconductor region 1, an entire portion or a portion on a side of the front surface of the semiconductor region 1 has an oxygen concentration of 2×10¹⁶ cm⁻³ or more and 5×10¹⁷ cm⁻³ or less, and an oxygen concentration from the front surface to the back surface of the semiconductor region 1 varies continuously. The semiconductor region 1 has composite defects 7 including oxygen and point defects.

The vertical diode in FIG. 7 is a non-punch-through diode in which the cathode region 3a and the drift region 4 are in contact with each other. The non-punch-through diode preferably has a maximum concentration of the composite defects 7 near an interface between the anode region 2a and the drift region 4. Reverse recovery characteristics of the vertical diode can be improved by forming the composite defects 7 near the interface between the anode region 2a and the drift region 4.

The vertical diode according to Embodiment 2 may be a punch-through diode as illustrated in FIG. 8. The punch-through diode further includes a field stop region 3c disposed between the cathode region 3a and the drift region 4 and having a higher concentration of the n-type impurities than the drift region 4. The field stop region 3c is included in the concept of the back surface structure in Embodiment 1. The punch-through diode preferably has the maximum concentration of the composite defects 7 near an interface between the cathode region 3a and the field stop region 3c. Reverse recovery characteristics of the vertical diode can be improved by forming the composite defects 7 near the interface between the cathode region 3a and the field stop region 3c.

### Embodiment 3

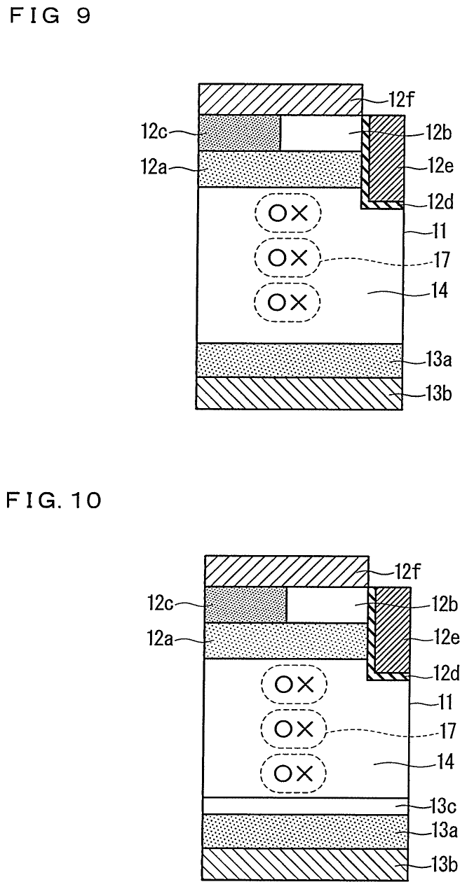

FIG. 9 is a partial cross-sectional view illustrating a main part of a configuration of a power semiconductor device according to Embodiment 3. From among components according to Embodiment 3, components different from the above-mentioned components will mainly be described below. The power semiconductor device according to Embodiment 3 is an insulated gate bipolar transistor (IGBT) having composite defects formed in the semiconductor region by the manufacturing method according to Embodiment 1.

The IGBT in FIG. 9 includes a semiconductor region 11, a base region 12a, an emitter region 12b, a base contact region 12c, a gate insulating film 12d, a trench gate electrode 12e, an emitter electrode 12f, a collector region 13a, and a collector electrode 13b. The base region 12a, the emitter region 12b, the base contact region 12c, the gate insulating film 12d, the trench gate electrode 12e, and the emitter electrode 12f are included in the concept of the front surface structure in Embodiment 1. The collector region 13a and the collector electrode 13b are included in the concept of the back surface structure in Embodiment 1.

The semiconductor region 11 is included in the semiconductor region in Embodiment 1, and is formed out of the silicon wafer. The semiconductor region 11 includes the collector region 13a including the p-type impurities. The semiconductor region 11 includes a drift region 14 disposed on the collector region 13a. The drift region 14 may include the n-type impurities at a relatively low concentration, or may not substantially include the impurities of the conductivity type. The base region 12a including the p-type impurities is disposed on the drift region 14. The base region 12a is separated from the collector region 13a by the drift region 14.

On the base region 12a, the emitter region 12b including the n-type impurities is selectively disposed, and the base contact region 12c including the p-type impurities at a relatively high concentration is selectively disposed. The emitter region 12b is separated from the drift region 14 by the base region 12a.

The trench gate electrode 12e faces the base region 12a that separates the emitter region 12b and the drift region 14 via the gate insulating film 12d. The gate insulating film 12d is formed of silicon oxide, for example, and the trench gate electrode 12e is formed of polysilicon, for example.

The emitter electrode 12f formed of aluminum, for example, is disposed on the emitter region 12b and the base contact region 12c. The emitter electrode 12f is electrically connected to the emitter region 12b and the base contact region 12c. The trench gate electrode 12e and the emitter electrode 12f are electrically isolated from each other. The collector electrode 13b is electrically connected to the collector region 13a.

In the semiconductor region 11, an entire portion or a portion on a side of the front surface of the semiconductor region 11 has an oxygen concentration of 2×10¹⁶ cm⁻³ or more and 5×10¹⁷ cm⁻³ or less, and an oxygen concentration from the front surface to the back surface of the semiconductor region 11 varies continuously. The semiconductor region 11 has composite defects 17 including oxygen and point defects.

The IGBT in FIG. 9 is a non-punch-through IGBT in which the collector region 13a and the drift region 14 are in contact with each other. The non-punch-through IGBT preferably has a maximum concentration of the composite defects 17 near an interface between the collector region 13a and the drift region 14. Reverse recovery characteristics of the IGBT can be improved by forming the composite defects 17 near the interface between the collector region 13a and the drift region 14.

The IGBT according to Embodiment 3 may be a punch-through IGBT as illustrated in FIG. 10. The punch-through IGBT further includes a field stop region 13c disposed between the collector region 13a and the drift region 14 and having a higher concentration of the n-type impurities than the drift region 14. The field stop region 13c is included in the concept of the back surface structure in Embodiment 1. The punch-through IGBT preferably has the maximum concentration of the composite defects 17 near an interface between the collector region 13a and the field stop region 13c. Reverse recovery characteristics of the IGBT can be improved by forming the composite defects 17 near the interface between the collector region 13a and the field stop region 13c.

<Modifications>

While the charged particle beam irradiating step is performed in step S5 in Embodiment 1, some point defects are originally present in the silicon wafer even when the charged particle beam irradiating step is not performed. The charged particle beam irradiating step in step S5 thus may not be performed. The charged particle beam irradiating step in step S5 is performed after the back surface structure forming step in step S4 in Embodiment 1, but may not be performed after the back surface structure forming step in step S4. For example, the charged particle beam irradiating step in step S5 may be performed after the oxygen introducing and deriving step in step S1.

While only one of introduction and derivation of oxygen into and from the silicon wafer is performed in the oxygen introducing and deriving step in step S1 in Embodiment 1, processing performed in the oxygen introducing and deriving step is not limited to the processing. For example, when the oxygen concentration of the silicon wafer is already sufficiently close to the equilibrium concentration before the oxygen introducing and deriving step, both introduction and derivation of oxygen into and from a single silicon wafer are sometimes performed in the oxygen introducing and deriving step.

While the front surface of the silicon wafer is subjected to the oxygen introducing and deriving step in Embodiment 1, a portion of the silicon wafer subjected to the oxygen introducing and deriving step is not limited to the front surface. For example, not only the front surface but also a side surface of the silicon wafer may be subjected to the oxygen introducing and deriving step.

While the silicon wafer is a simple Si wafer in description made above, the silicon wafer is not limited to the Si wafer. For example, the silicon wafer may be a wafer formed of a wide bandgap semiconductor, such as an SiC wafer.

While materials for electrodes, a film formation method, concentrations of the p-type and n-type regions, and the like are not particularly described in description made above, a typical design condition for the power semiconductor device may be applied to suit applications. A metal oxide semiconductor field effect transistor (MOSFET), a Schottky barrier diode (SBD), a PN junction diode (PND), and the like may be formed by the manufacturing method described in Embodiment 1.

Embodiments and modifications can freely be combined with each other, and can be modified or omitted as appropriate.

The foregoing description is in all aspects illustrative and not restrictive. It is understood that numerous unillustrated modifications can be devised.

### EXPLANATION OF REFERENCE SIGNS

1, 11 semiconductor region, 2a anode region, 2b anode electrode, 3a cathode region, 3b cathode electrode, 7, 17 composite defect, 12a base region, 12b emitter region, 12c base contact region, 12d gate insulating film, 12e trench gate electrode, 12f emitter electrode, 13a collector region, 13b collector electrode.

1. A semiconductor device manufacturing method comprising:
a first step of introducing oxygen to increase an oxygen concentration of a silicon wafer when the oxygen concentration of the silicon wafer is lower than a predetermined threshold, and deriving oxygen to decrease the oxygen concentration of the silicon wafer when the oxygen concentration of the silicon wafer is higher than the threshold;
a second step of forming a first surface structure in a first surface of the silicon wafer after the first step;
a third step of grinding the silicon wafer from a second surface opposite the first surface after the first step; and
a fourth step of forming a second surface structure in the second surface of the silicon wafer after the third step.

2. The semiconductor device manufacturing method according to claim 1, wherein
in the first step, the silicon wafer is annealed in a state of being in contact with at least one of an oxide film or an oxygen atmosphere,
t≥{d/[2×√D×erfc⁻¹(1×10¹⁵/Cₛ)]}²,
D=0.28×exp(−2.53/kT), and
Cₛ=6×10²²exp(−1.61/kT) hold,
where t (seconds) is an annealing time, T (K) is an annealing temperature of 1000° C. or more and 1300° C. or less, d (cm) is a thickness of the silicon wafer after the third step, k is the Boltzmann constant in eV/K, and erfc⁻¹ is an inverse function of a complementary error function erfc.

3. The semiconductor device manufacturing method according to claim 1, further comprising:
a fifth step of irradiating the silicon wafer with a charged particle beam to form point defects after the first step; and
a sixth step of performing annealing for at least one of formation of composite defects including the point defects and oxygen or annihilation of some of the point defects after the fifth step.

4. The semiconductor device manufacturing method according to claim 3, wherein
in the fifth step, the first surface or the second surface of the silicon wafer is irradiated with an electron beam as the charged particle beam to form the point defects in an entire portion of the silicon wafer after the third step.

5. The semiconductor device manufacturing method according to claim 3, wherein
in the fifth step, the first surface or the second surface of the silicon wafer is irradiated with protons or helium ions as the charged particle beam to form the point defects in a local portion of the silicon wafer after the third step.

6. The semiconductor device manufacturing method according to claim 1, wherein
an entire portion or a portion on a side of the first surface of the silicon wafer after the third step has an oxygen concentration of 2×10¹⁶ cm⁻³ or more and 5×10¹⁷ cm⁻³ or less.

7. The semiconductor device manufacturing method according to claim 1, wherein
the silicon wafer before the first step has an oxygen concentration of 1×10¹⁵ cm⁻³ or more and 1×10¹⁸ cm⁻³ or less.

8. A semiconductor device comprising:
a semiconductor region of a silicon wafer having a composite defect including oxygen and a point defect;
a first surface structure disposed in a first surface of the semiconductor region; and
a second surface structure disposed in a second surface opposite the first surface of the semiconductor region, wherein
an entire portion or a portion on a side of the first surface of the semiconductor region has an oxygen concentration of 2×10¹⁶ cm⁻³ or more and 5×10¹⁷ cm⁻³ or less, and an oxygen concentration from the first surface to the second surface of the semiconductor region increases or decreases monotonically from the first surface toward the second surface.
